(19) United States
(12) Patent Application Publication
(10) Pub. No.: US 2024/0251497 A1
(43) Pub. Date: Jul. 25, 2024

(54) CIRCUIT BOARD MOUNTING SUPPORT

(71) Applicant: ACCTON TECHNOLOGY CORPORATION, Hsinchu (TW)

(72) Inventor: WEI-RONG LEE, Zhubei (TW)

(73) Assignee: ACCTON TECHNOLOGY CORPORATION, Hsinchu (TW)

(21) Appl. No.: 18/200,060

(22) Filed: May 22, 2023

(30) Foreign Application Priority Data
Jan. 19, 2023 (CN) 202320149183.8

(51) Int. Cl. H05K 1/02

(52) U.S. Cl. CPC H05K 1/0203

(57) ABSTRACT

A circuit board mounting support adapted to mount a circuit board includes a fixing device including a first fixing member and a second fixing member, a heat dissipating device having a through hole corresponding to the second fixing member and being in contact with a surface of an electronic component disposed on the circuit board, a first compression spring exerting an elastic force on the heat dissipating device along a direction, and a restricting member disposed on the heat dissipating device, detachably engaged with the second fixing member, and restricting the heat dissipating device from moving in directions other than the direction of the elastic force. The second fixing member has an abutting portion and a fixing portion detachably fixed on the first fixing member and passes through the through hole. Two opposite ends of the first compression spring respectively abut against the abutting portion and the heat dissipating device.

### BACKGROUND OF THE INVENTION

### Technical Field

The present disclosure relates generally to a circuit board mounting support, and more particularly to a circuit board mounting support including a heat dissipating device.

### Description of Related Art

Conventionally, different electronic devices generate different levels of heat during operating, especially an electronic assembly including an electronic component required to operate intensively and generating a large amount of heat during operating, e.g. central processing unit (CPU), graphics processing unit (GPU), etc. The heat would be stored in an electronic device, increasing an overall temperature of the electronic device, thereby not only greatly affecting the performance of the electronic assembly, but also weakening the stability and the function of the electronic assembly.

In order to prevent the heat from affecting the operation of the electronic component, a heat dissipating device is generally mounted on the electronic component. The heat dissipating device dissipates the heat generated by the electronic component by contacting the electronic component, achieving a function of reducing a temperature of the electronic component.

Although a conventional heat dissipating device could solve the problem of the heat generated by the electronic component storing in the electronic device, the heat dissipating device easily generates an uneven pressure or a collision to the electronic component because of shock or vibration, causing cracking and damage to the electronic component, which makes the electronic assembly malfunction, and reducing the fitting strength between the heat dissipating device and the electronic component, which reduces a contacting area between the heat dissipating device and the electronic component, thereby affecting the heat dissipating performance.

### BRIEF SUMMARY OF THE INVENTION

In view of the above, the primary objective of the present disclosure is to provide a circuit board mounting support, which could improve a fitting strength between a heat dissipating device and an electronic component and relieve the problem that the heat dissipating device easily generates an uneven pressure or a collision to the electronic component because of shock or vibration.

The present disclosure provides a circuit board mounting support adapted to mount a circuit board, wherein at least one electronic component is disposed on the circuit board. The circuit board mounting support includes a fixing device, a heat dissipating device, a first compression spring, and a restricting member. The fixing device includes a first fixing member and a second fixing member having an abutting portion and a fixing portion detachably fixed on the first fixing member to fix the circuit board on the fixing device. The heat dissipating device has a through hole corresponding to the second fixing member. The second fixing member passes through the through hole to be fixed on the first fixing member. The heat dissipating device is in contact with a surface of the at least one electronic component of the circuit board. Two opposite ends of the first compression spring respectively abut against the abutting portion of the second fixing member and the heat dissipating device. The restricting member is disposed on the heat dissipating device and is detachably engaged with the second fixing member. The first compression spring exerts an elastic force on the heat dissipating device along a direction. The restricting member restricts the heat dissipating device from moving in directions other than the direction of the elastic force.

In an embodiment, the restricting member includes a tension spring: an end of the second fixing member opposite to the fixing portion has a head: two opposite ends of the tension spring are respectively connected to the head and the heat dissipating device.

In an embodiment, the restricting member includes a locking member and a top connecting member: an end of the locking member is pivotally connected to the top connecting member, and another end of the locking member pivots to a position to be engaged with the head of the second fixing member; the tension spring is connected to the top connecting member and is connected to the head through the locking member.

In an embodiment, the restricting member includes a fixed seat fixed on the heat dissipating device and a bottom connecting member pivotally connected to the fixed seat: two opposite ends of the tension spring are respectively connected to the top connecting member and the bottom connecting member; the tension spring is connected to the heat dissipating device through the bottom connecting member and the fixed seat.

In an embodiment, the head of the second fixing member has an annular protrusion, and the locking member has a slot corresponding to the annular protrusion.

In an embodiment, the restricting member includes an annular seat and a fixing ring: the second fixing member correspondingly passes through the annular seat and the fixing ring: a side of the annular seat is fixed on the heat dissipating device, and another side of the annular seat has a stop portion and an opening: the fixing ring has a blocking portion protruding from an outer surface of the fixing ring: the blocking portion passes through the opening along an axial direction of the annular seat and rotates by an angle around the axial direction to abut against the stop portion: the heat dissipating device and the stop portion restrict the fixing ring from moving in the axial direction.

In an embodiment, the restricting member includes a second compression spring disposed between the fixing ring and the abutting portion: when the blocking portion abuts against the stop portion, two ends of the second compression spring respectively abut against an inner wall of the fixing ring and the abutting portion of the second fixing member.

In an embodiment, the first compression spring and the second compression spring are respectively disposed on two sides of the abutting portion of the second fixing member that face back to back.

In an embodiment, the second fixing member includes a first fixing unit and a second fixing unit having the abutting portion and the fixing portion: the first fixing unit is detachably connected to a top of the second fixing unit: the second compression spring fits around the first fixing unit.

In an embodiment, the fixing ring has a first through hole and a second through hole communicating with the first through hole in the axial direction: a diameter of the first through hole is smaller than a diameter of the second through hole; two opposite ends of the first fixing unit respectively have a head and a connecting portion, wherein an outer diameter of the head is greater than the diameter of the first through hole; the connecting portion passes through the first through hole and the second through hole in sequence to be connected to the top of the second fixing unit: an outer diameter of the abutting portion of the second fixing unit is greater than the diameter of the first through hole and smaller than the diameter of the second through hole.

In an embodiment, the heat dissipating device includes a plate and a heat dissipating member connected to the plate and being in contact with the surface of the at least one electronic component on the circuit board. The plate has the through hole. Two opposite ends of the first compression spring respectively abut against the abutting portion of the second fixing member and the plate.

With the aforementioned design, the heat dissipating device could be well kept in a state attached to the at least one electronic component, thereby continuously providing a stable heat dissipating effect and effectively preventing the problem that the heat dissipating device generates the uneven pressure or the collision to the at least one electronic component. For example, when the heat dissipating device moves in the direction due to vibration, the restricting member could restrict the heat dissipating device from moving relative to the circuit board: or when the heat dissipating device moves in a direction opposite to the direction, the first compression spring could make the heat dissipating device keep in the state attached to the at least one electronic component. In this way, the heat dissipating device could be kept in the state attached to the at least one electronic component for not only continuously providing a stable heat dissipating effect, but also effectively preventing the problem of the heat dissipating device generating the uneven pressure or the collision to the at least one electronic component.

### BRIEF DESCRIPTION OF THE SEVERAL VIEWS OF THE DRAWINGS

The present disclosure will be best understood by referring to the following detailed description of some illustrative embodiments in conjunction with the accompanying drawings, in which

FIG. 1 is a perspective view of the circuit board mounting support according to a first embodiment of the present disclosure:

FIG. 2 is a top view of FIG. 1:

FIG. 3 is a sectional view along the A-A line in FIG. 2:

FIG. 4 is a schematic side view, showing a part of the circuit board mounting support according to the first embodiment of the present disclosure:

FIG. 5 is a schematic view of the circuit board mounting support according to the first embodiment of the present disclosure, showing the use of the circuit board mounting support:

FIG. 6 is a schematic view of the circuit board mounting support according to the first embodiment of the present disclosure, showing the use of the circuit board mounting support:

FIG. 7 is a schematic view of the circuit board mounting support according to the first embodiment of the present disclosure, showing the use of the circuit board mounting support:

FIG. 8 is a perspective view of the circuit board mounting support according to a second embodiment of the present disclosure:

FIG. 9 is a top view of FIG. 8:

FIG. 10 is a sectional view along the B-B line in FIG. 9;

FIG. 11 is a schematic view of the circuit board mounting support according to the second embodiment of the present disclosure, showing the use of the circuit board mounting support: and

FIG. 12 is a schematic view of the circuit board mounting support according to the second embodiment of the present disclosure, showing the use of the circuit board mounting support.

### DETAILED DESCRIPTION OF THE INVENTION

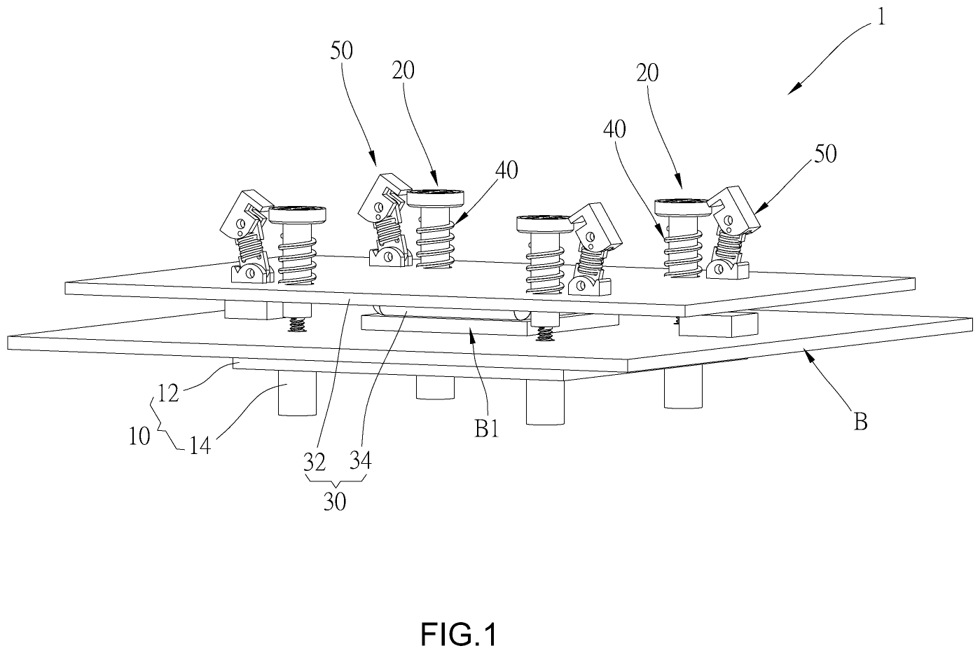

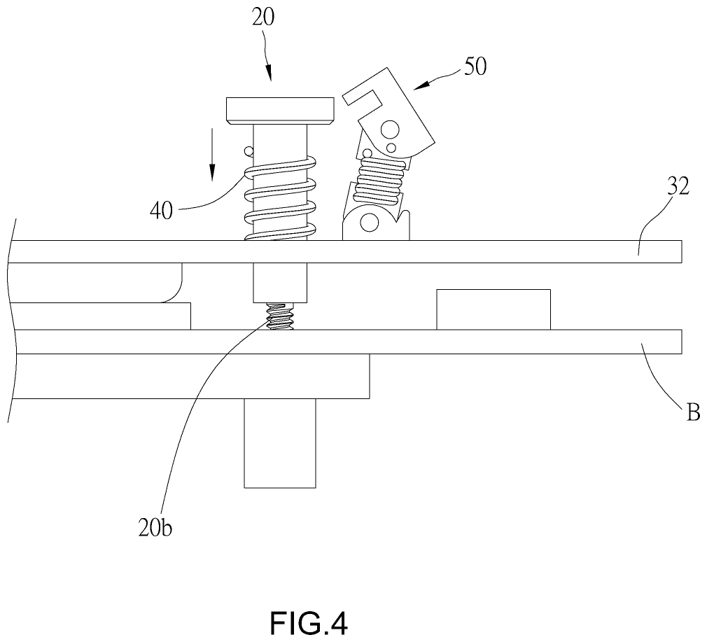

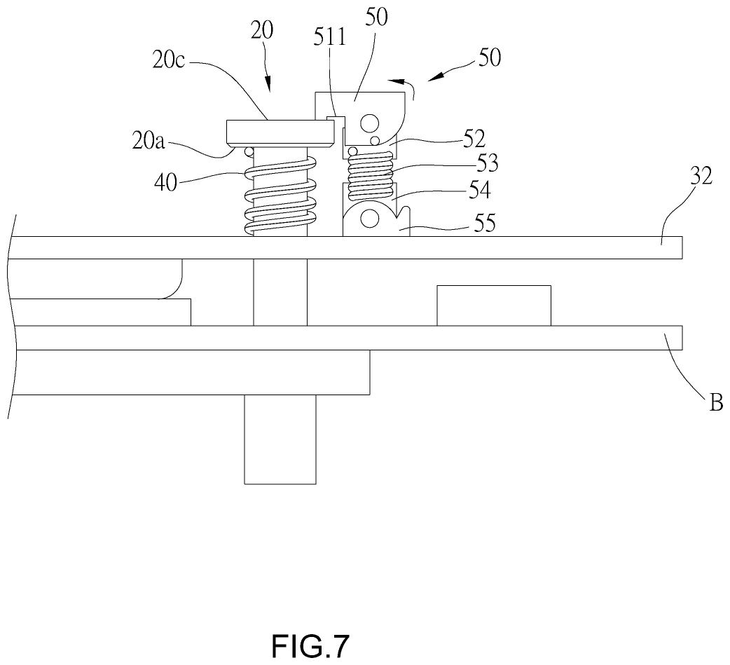

A circuit board mounting support 1 according to a first embodiment of the present disclosure is illustrated in FIG. 1 to FIG. 7 and is adapted to mount a circuit board B, wherein at least one electronic component B1 is disposed on the circuit board B. The circuit board mounting support 1 includes a fixing device including a first fixing member 10 and a plurality of second fixing members 20, a heat dissipating device 30, a plurality of first compression springs 40, and a plurality of restricting members 50.

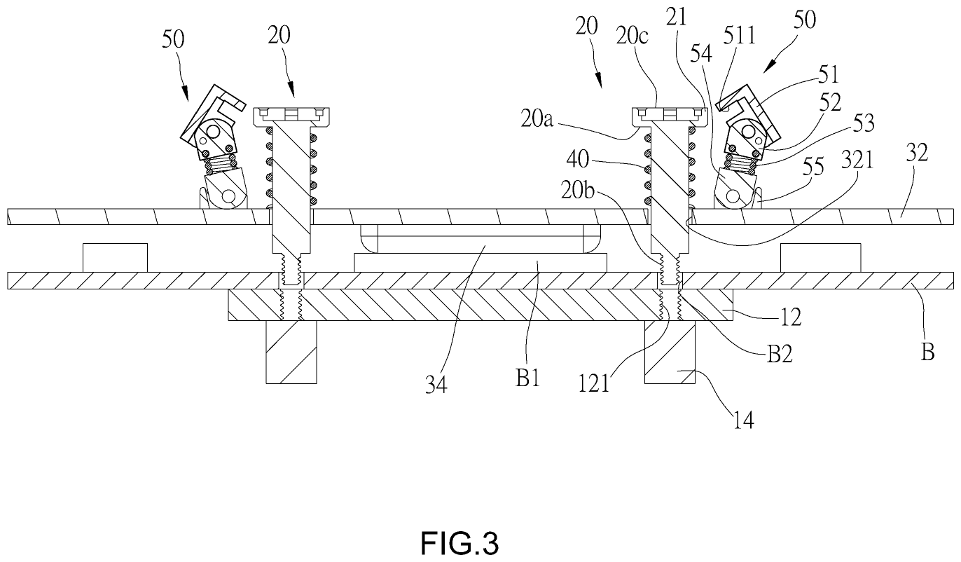

As shown in FIG. 3, the first fixing member 10 is disposed on a bottom of the circuit board B and includes a bottom plate 12 and a plurality of support posts 14 disposed on a bottom of the bottom plate 12. The circuit board B is disposed on a top of the bottom plate 12. The support posts 14 have a function of supporting the circuit board B through the bottom plate 12, effectively reducing a risk of falling off or solder cracking of the at least one electronic component B1 due to vibration or deformation of the circuit board B.

Each of the second fixing members 20 has an abutting portion 20a and a fixing portion 20b detachably fixed on the first fixing member 10 for fixing the circuit board B on the first fixing member 10. In the current embodiment, each of the second fixing members 20 is a bolt as an example, wherein the abutting portion 20a and the fixing portion 20b are respectively located on two opposite ends of a shank of the bolt: the fixing portion 20b has an outer thread: the bottom plate 12 of the first fixing member 10 has a plurality of threaded holes 121 respectively corresponding to one of the bolts, and the circuit board B has a plurality of through holes B2 respectively corresponding to one of the bolts: an outer diameter of the shank of each of the bolts is greater than both an outer diameter of the fixing portion 20b of each of the bolts and a diameter of each of the through holes B2 of the circuit board B: in this way, when the circuit board B is disposed on the bottom plate 12, the fixing portion 20b of each of the bolts could pass through one of the through holes B2 of the circuit board B and then could be engaged with one of the threaded holes 121 of the bottom plate 12, thereby the circuit board B could be clamped between the shank of each of the bolts and the bottom plate 12.

In the current embodiment, the first fixing member 10 includes the bottom plate 12 and the support posts 14 as an example. In other embodiments, the first fixing member 10 could be engaged with the second fixing members 20 in other ways for fixing the circuit board B on the fixing device; for example, the first fixing member 10 could only include the support posts 14 and not include the bottom plate 12, wherein each of the support posts 14 has a threaded hole corresponding to one of the bolts: the fixing portion 20b of each of the bolts could pass through one of the through hole B2 of the circuit board B and then could be screwed into the threaded hole of one of the support posts 14, achieving the effect of fixing the circuit board B on the fixing device.

The heat dissipating device 30 includes a plate 32 and a heat dissipating member 34 connected to the plate 32 and contacting a surface of the at least one electronic component B1 on the circuit board B for dissipating a heat generated by the at least one electronic component B1, achieving an effect of reducing a temperature of the at least one electronic component B1. The plate 32 has a plurality of through holes 321 respectively corresponding to one of the second fixing members 20, wherein a diameter of each of the through holes 321 of the plate 32 is slightly greater than the outer diameter of the shank of each of the bolts. Each of the second fixing members 20 passes through one of the through holes 321 of the plate 32. Each of the first compression springs 40 fits around the shank of one of the bolts, wherein two opposite ends of each of the first compression springs 40 respectively abut against the abutting portion 20a of one of the second fixing members 20 and the plate 32. In this way, when the bottom plate 12, the circuit board B, and the heat dissipating device 30 are stacked in order, the fixing portion 20b of each of the bolts could pass through one of the through holes 321 of the plate 32 and one of the through holes B2 of the circuit board B to be screwed into one of the threaded holes 121 of the bottom plate 12 for correspondingly compressing one of the first compression springs 40, making the first compression springs 40 exert an elastic force on the plate 32 along a direction, thereby driving the heat dissipating member 34 to move to a position tightly attached to the at least one electronic component B1 on the circuit board B, so that the heat dissipating effect could be enhanced.

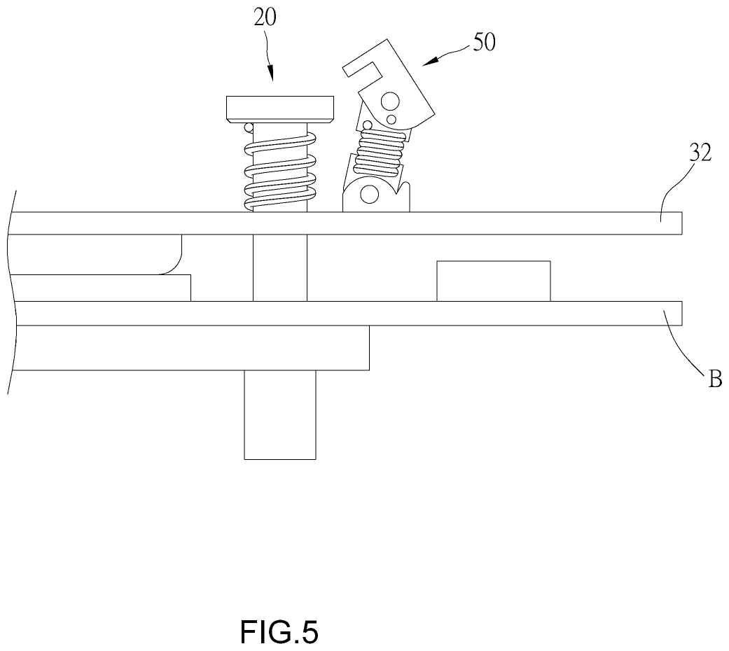

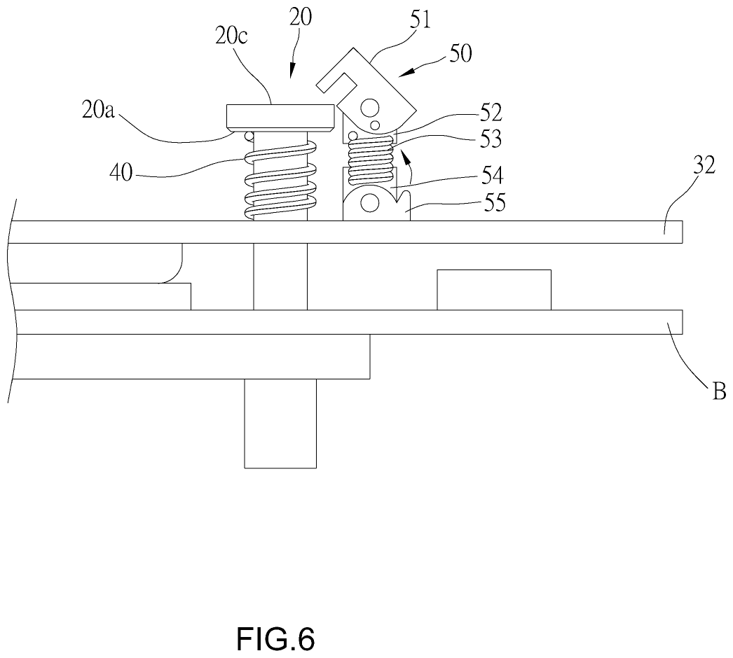

In the current embodiment, an end of each of the restricting members 50 is connected to the heat dissipating device 30, and another end of each of the restricting members 50 is detachably engaged with one of the second fixing members 20. Each of the restricting members 50 includes a locking member 51, a top connecting member 52, a tension spring 53, a bottom connecting member 54, and a fixed seat 55. The fixed seat 55 is fixed on the plate 32. The bottom connecting member 54 is pivotally connected to the fixed seat 55. Two opposite ends of the tension spring 53 are respectively connected to the top connecting member 52 and the bottom connecting member 54. An end of the locking member 51 is pivotally connected to the top connecting member 52. An end of each of the second fixing members 20 opposite to the fixing portion 20b has a head 20c. The two opposite ends of the tension spring 53 are respectively connected to the head 20c via the locking member 51 and the plate 32 via the bottom connecting member 54 and the fixed seat 55. The head 20c of each of the second fixing member 20 has an annular protrusion 21. The locking member 51 of each of the restricting members 50 has a slot 511 correspondingly matching with the annular protrusion 21. In this way, when each of the second fixing members 20 is engaged with one of the threaded holes 121 of the bottom plate 12 as shown in FIG. 5, the bottom connecting member 54 of each of the restricting members 50 could pivot relative to the first fixing member 10 as shown in FIG. 6 for driving the corresponding locking member 51 to move to a position close to the head 20c of one of the second fixing members 20 via the corresponding top connecting member 52 and the corresponding tension spring 53, and the corresponding locking member 51 could be pivoted to move another end of the corresponding locking member 51 to a position engaged with the head 20c of one of the second fixing members 20, thereby the slot 511 of each of the locking members 51 and the annular protrusion 21 of one of the second fixing members 20 could be mutually stuck and fixed.

In this way, when the heat dissipating device 30 is about to be moved along a direction opposite to the direction of the elastic force of the first compression springs 40 due to vibration or other factors, each of the first compression springs 40 could urge the plate 32 to move toward the direction of the elastic force of the first compression springs 40; when the heat dissipating device 30 is about to be moved along a direction identical to the direction of the elastic force of the first compression springs 40, each of the restricting members 50 could provide a force in a direction opposite to the direction of the elastic force of the first compression springs 40 for restricting the heat dissipating device 30 from moving toward the direction of the elastic force of the first compression springs 40; for example, when the plate 32 of the heat dissipating device 30 moves or bends upward, each of the first compression springs 40 could push the plate 32 for preventing the heat dissipating member 34 from leaving the position of contacting the surface of the at least one electronic component B1 on the circuit board B: when the plate 32 of the heat dissipating device 30 moves or bends downward, the tension spring 53 of each of the restricting members 50 could pull the plate 32 for preventing the heat dissipating member 34 from colliding with the surface of the at least one electronic component B1 on the circuit board B.

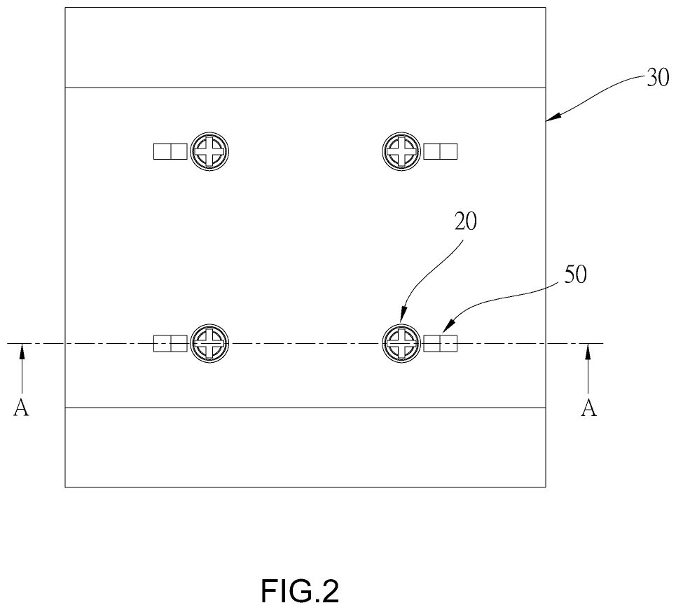

In the current embodiment, the second fixing members 20 are respectively disposed at a position adjacent to four corners of the heat dissipating member 34; as shown in FIG. 2, the second fixing members 20 are divided into two groups of two second fixing members 20, and the restricting members 50 corresponding to one of the two groups of the second fixing members 20 are respectively disposed at a position located on two opposite outsides of the group of the second fixing members 20. Additionally, in the current embodiment, the second fixing members 20, the first compression springs 40, and the restricting members 50 are respectively plural as an example. In practice, the number of the second fixing member 20, the number of the first compression spring 40, and the number of the restricting member 50 could be respectively one.

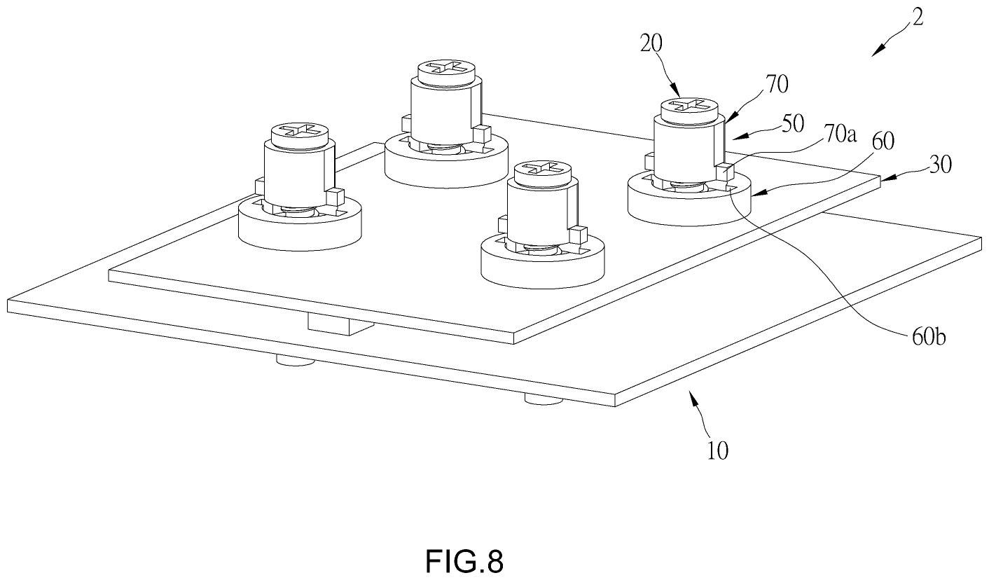

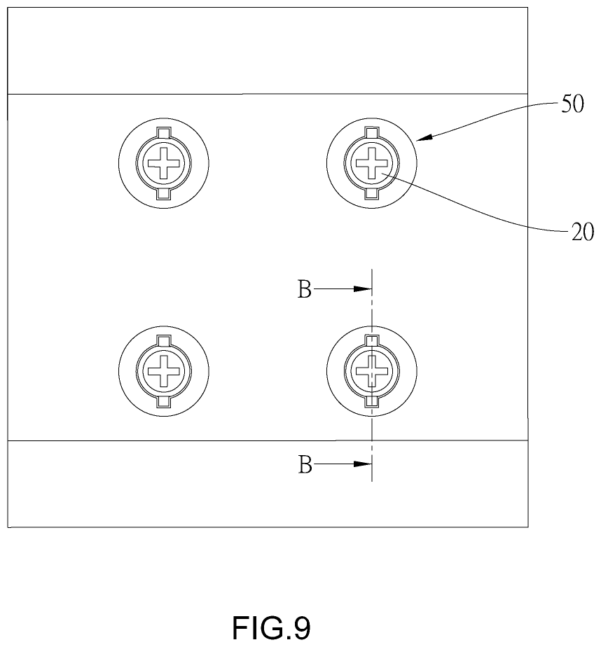

A circuit board mounting support 2 according to a second embodiment of the present disclosure is illustrated in FIG. 8 to FIG. 12, and has almost the same structure as that of the first embodiment, which similarly includes a first fixing member 10, a plurality of second fixing members 20, a heat dissipating device 30, a plurality of first compression springs 40, and a plurality of restricting members 50, except that each of the restricting members 50 includes an annular seat 60 and a fixing ring 70, and the structure of the second fixing members 20 is different from that of the second fixing members 20 of the first embodiment.

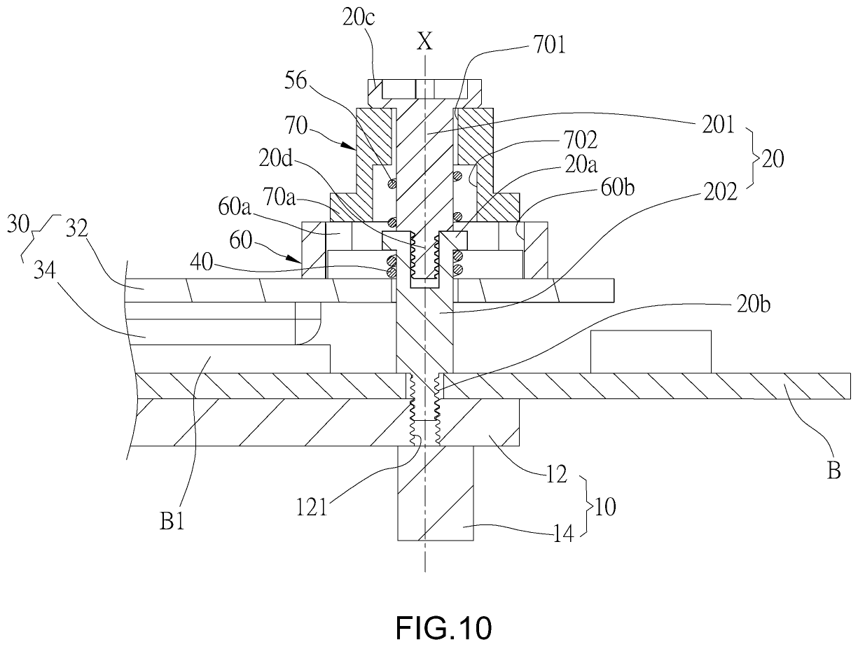

As shown in FIG. 10, each of the second fixing members 20 correspondingly passes through the annular seat 60 and the fixing ring 70 of one of the restricting members 50 and includes a first fixing unit 201 and a second fixing unit 202 having an abutting portion 20a and a fixing portion 20b, wherein the first fixing unit 201 is detachably connected to a top of the second fixing unit 202. Each of the first compression springs 40 fits around the second fixing unit 202 of one of the second fixing members 20, wherein two opposite ends of each of the first compression springs 40 respectively abut against the abutting portion 20a of the second fixing unit 202 of the corresponding second fixing member 20 and a plate 32.

In the current embodiment, both the first fixing unit 201 and the second fixing unit 202 are a bolt as an example, wherein the second fixing unit 202 has almost the same structure as the second fixing members 20 of the first embodiment, except that a top end of the second fixing unit 202 has a threaded hole matching with an external thread of the first fixing unit 201, thereby the first fixing unit 201 could be connected to the top of the second fixing unit 202 through screwing.

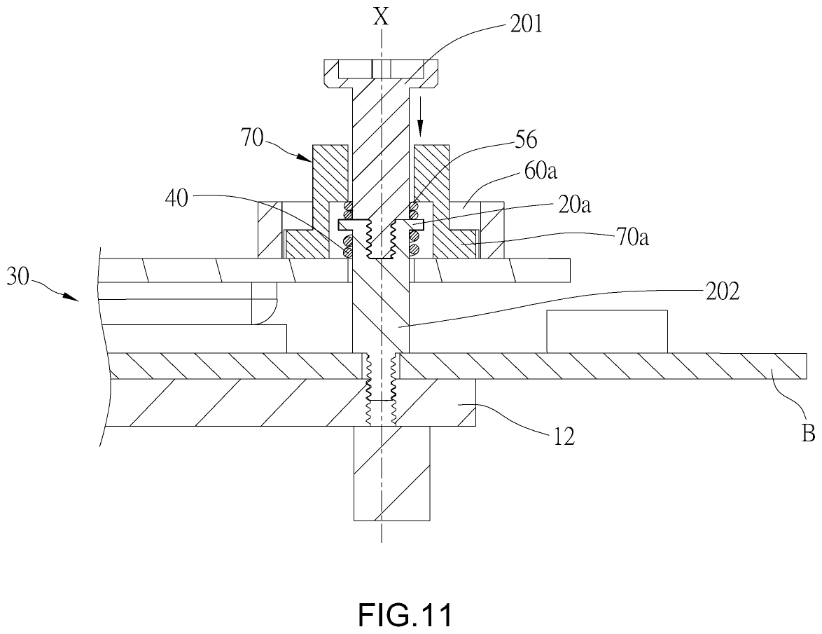

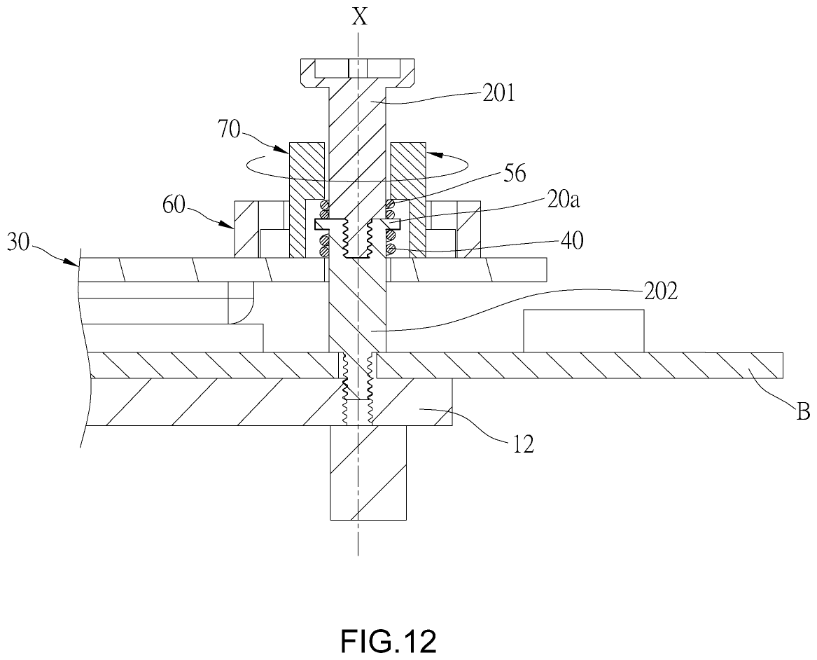

As shown in FIG. 10, a side of the annular seat 60 of each of the restricting members 50 is fixed on the plate 32, and an opposite side of the annular seat 60 of each of the restricting members 50 has a stop portion 60a and an opening 60b. A position of the fixing ring 70 close to a bottom of the corresponding fixing ring 70 has a blocking portion 70a protruding from an outer surface of the corresponding fixing ring 70. The blocking portion 70a could pass through the opening 60b of one of the annular seats 60 along an axial direction X of the corresponding annular seat 60 to enter the corresponding annular seat 60 as shown in FIG. 11, and could rotate by an angle around the axial direction X to move to a position abutting against the stop portion 60a of the corresponding annular seat 60 as shown in FIG. 12, wherein a distance between the plate 32 and the stop portion 60a in the axial direction X is slightly greater than a thickness of the blocking portion 70a in the axial direction X. In this way, the blocking portion 70a could rotate in a space between the plate 32 and the stop portion 60a, and the plate 32 and the stop portion 60a could abut against the fixing ring 70 to restrict the fixing ring 70 from moving in the axial direction X.

The fixing ring 70 of each of the restricting members 50 has a first through hole 701 and a second through hole 702 communicating with the first through hole 701 in the axial direction X, wherein a diameter of the first through hole 701 is smaller than a diameter of the second through hole 702. Two opposite ends of the first fixing unit 201 respectively have a head 20c and a connecting portion 20d. An outer diameter of the head 20c is greater than the diameter of the first through hole 701. The connecting portion 20d has an outer thread and could pass through the first through hole 701 and the second through hole 702 in sequence to be connected to the top of the second fixing unit 202. An outer diameter of the abutting portion 20a of the second fixing unit 202 is greater than the diameter of the first through hole 701 and smaller than the diameter of the second through hole 702. In this way, upon mounting, firstly the second fixing unit 202 of each of the second fixing members 20 is mounted on a bottom plate 12, and then the first fixing unit 201 of each of the second fixing members 20 is engaged with the top of the second fixing unit 202 of the corresponding second fixing member 20 after passing through the first through hole 701 and the second through hole 702 of one of the fixing rings 70, thereby positioning the corresponding fixing ring 70 between the head 20c of the first fixing unit 201 of the corresponding second fixing member 20 and the plate 32.

In the current embodiment, each of the restricting members 50 includes a second compression spring 56. Each of the first compression springs 40 and the second compression spring 56 are respectively disposed on two sides of the abutting portion 20a of the second fixing unit 202 that face back to back. The second compression spring 56 fits around the first fixing unit 201 and is disposed between the fixing ring 70 and the abutting portion 20a. When the blocking portion 70a abuts against the stop portion 60a, two ends of the second compression spring 56 respectively abut against an inner wall of the corresponding fixing ring 70 and the abutting portion 20a of the corresponding second fixing member 20. Upon manipulating, the fixing ring 70 could be pressed to make the blocking portion 70a of the fixing ring 70 pass through the opening 60b of the annular seat 60 along the axial direction X to enter the annular seat 60 and compress the second compression spring 56 as shown in FIG. 11, and then the blocking portion 70a could be rotated by the angle around the axial direction X to move to the position abutting against the stop portion 60a.

In this way, when the plate 32 of the heat dissipating device 30 moves or bends upward, each of the first compression springs 40 could push the plate 32 for preventing a heat dissipating member 34 from leaving a position contacting a surface of at least one electronic component B1 on a circuit board B: when the plate 32 of the heat dissipating device 30 moves or bends downward, the plate 32 could drive the fixing ring 70 of each of the restricting members 50 to press the corresponding second compression spring 56 via the corresponding annular seat 60; at this time the second compression spring 56 of each of the restricting members 50 could provide an upward elastic force to drive the corresponding annular seat 60 to pull the plate 32 via the corresponding fixing ring 70, thereby preventing the heat dissipating member 34 from colliding with the surface of the at least one electronic component B1 of the circuit board B.

In the current embodiment, the second fixing members 20, the first compression springs 40, the restricting members 50, the annular seats 60, and the fixing rings 70 are respectively plural as an example. In practice, the number of the second fixing member 20, the number of the first compression spring 40, the number of the restricting member 50, the number of the annular seat 60, and the number of the fixing ring 70 could respectively be one.

With the aforementioned design, when the heat dissipating device 30 moves in the direction the same as the direction of the elastic force of the first compression springs 40 or moves in the direction opposite to the direction of the elastic force of the first compression springs 40, the heat dissipating device 30 could be restricted from moving relative to the circuit board B through the first compression springs 40 and the restricting members 50. In this way, the circuit board mounting supports 1,2 of the present disclosure not only could allow the heat dissipating device 30 to be kept in a state attached to the at least one electronic component B1 to provide a stable heat dissipating effect, but also could effectively prevent the problem of the heat dissipating device 30 generating an uneven pressure or a collision to the at least one electronic component B1.

It must be pointed out that the embodiments described above are only some preferred embodiments of the present disclosure. All equivalent structures which employ the concepts disclosed in this specification and the appended claims should fall within the scope of the present disclosure.

What is claimed is:

1. A circuit board mounting support adapted to mount a circuit board, wherein at least one electronic component is disposed on the circuit board: the circuit board mounting support comprises:
a fixing device comprising a first fixing member and a second fixing member having an abutting portion and a fixing portion detachably fixed on the first fixing member to fix the circuit board on the fixing device;
a heat dissipating device having a through hole corresponding to the second fixing member, wherein the second fixing member passes through the through hole to be fixed on the first fixing member; the heat dissipating device is in contact with a surface of the at least one the electronic component on the circuit board;
a first compression spring, wherein two opposite ends of the first compression spring respectively abut against the abutting portion of the second fixing member and the heat dissipating device; and
a restricting member disposed on the heat dissipating device and detachably engaged with the second fixing member;
wherein the first compression spring exerts an elastic force on the heat dissipating device along a direction: the restricting member restricts the heat dissipating device from moving in directions other than the direction of the elastic force.

2. The circuit board mounting support as claimed in claim 1, wherein the restricting member comprises a tension spring: an end of the second fixing member opposite to the fixing portion has a head: two opposite ends of the tension spring are respectively connected to the head and the heat dissipating device.

3. The circuit board mounting support as claimed in claim 2, wherein the restricting member comprises a locking member and a top connecting member; an end of the locking member is pivotally connected to the top connecting member, and another end of the locking member pivots to a position to be engaged with the head of the second fixing member; the tension spring is connected to the top connecting member and is connected to the head through the locking member.

4. The circuit board mounting support as claimed in claim 3, wherein the restricting member comprises a fixed seat fixed on the heat dissipating device and a bottom connecting member pivotally connected to the fixed seat: two opposite ends of the tension spring are respectively connected to the top connecting member and the bottom connecting member; the tension spring is connected to the heat dissipating device through the bottom connecting member and the fixed seat.

5. The circuit board mounting support as claimed in claim 3, wherein the head of the second fixing member has an annular protrusion, and the locking member has a slot corresponding to the annular protrusion.

6. The circuit board mounting support as claimed in claim 1, wherein the restricting member comprises an annular seat and a fixing ring: the second fixing member correspondingly passes through the annular seat and the fixing ring: a side of the annular seat is fixed on the heat dissipating device, and another side of the annular seat has a stop portion and an opening: the fixing ring has a blocking portion protruding from an outer surface of the fixing ring: the blocking portion passes through the opening along an axial direction of the annular seat and rotates by an angle around the axial direction to abut against the stop portion: the heat dissipating device and the stop portion restrict the fixing ring from moving in the axial direction.

7. The circuit board mounting support as claimed in claim 6, wherein the restricting member comprises a second compression spring disposed between the fixing ring and the abutting portion: when the blocking portion abuts against the stop portion, two ends of the second compression spring respectively abut against an inner wall of the fixing ring and the abutting portion of the second fixing member.

8. The circuit board mounting support as claimed in claim 7, wherein the first compression spring and the second compression spring are respectively disposed on two sides of the abutting portion of the second fixing member that face back to back.

9. The circuit board mounting support as claimed in claim 8, wherein the second fixing member comprises a first fixing unit and a second fixing unit having the abutting portion and the fixing portion: the first fixing unit is detachably connected to a top of the second fixing unit: the second compression spring fits around the first fixing unit.

10. The circuit board mounting support as claimed in claim 9, wherein the fixing ring has a first through hole and a second through hole communicating with the first through hole in the axial direction: a diameter of the first through hole is smaller than a diameter of the second through hole; two opposite ends of the first fixing unit respectively have a head and a connecting portion, wherein an outer diameter of the head is greater than the diameter of the first through hole: the connecting portion passes through the first through hole and the second through hole in sequence to be connected to the top of the second fixing unit: an outer diameter of the abutting portion of the second fixing unit is greater than the diameter of the first through hole and smaller than the diameter of the second through hole.

11. The circuit board mounting support as claimed in claim 1, wherein the heat dissipating device comprises a plate and a heat dissipating member connected to the plate and being in contact with the surface of the at least one electronic component on the circuit board: the plate has the through hole; two opposite ends of the first compression spring respectively abut against the abutting portion of the second fixing member and the plate.
